(19) United States
(12) Patent Application Publication
(10) Pub. No.: US 2010/0024671 A1
(43) Pub. Date: Feb. 4, 2010

(54) SOLVENT-ASSISTED EMBOSSING OF FLEXOGRAPHIC PRINTING PLATES

(76) Inventors: Mikhail L. Pekurovsky, Bloomington, MN (US); Ryan T. Woldt, Minneapolis, MN (US)

Correspondence Address: 3M INNOVATIVE PROPERTIES COMPANY, PO BOX 33427, ST. PAUL, MN, 55133-3427, US

(21) Appl. No.: 12/514,886

(22) PCT Filed: Nov. 5, 2007
(86) PCT No.: PCT/US07/83569

§ 371 Date: May 14, 2009

Related U.S. Application Data
(60) Provisional application No. 60/865,979, filed on Nov. 15, 2006.

(51) Int. Cl. B41N 1/00; G03F 7/20

(52) U.S. Cl. 101/395; 430/306

(57) ABSTRACT

Methods of forming a flexographic printing plate are described and include disposing a polymeric substrate onto a master tool having a plurality of recesses defining a master tool pattern. A solvent is disposed within the recesses. Then, the solvent is diffused into the polymeric substrate to form a substrate relief pattern that is complementary to the master pattern. The substrate relief pattern is then cured to form a flexographic printing plate. Flexographic printing plates are also described.

### FIELD

This disclosure relates to flexographic printing plates; and more specifically to solvent-assisted embossing of flexographic printing plates.

### BACKGROUND

Flexographic printing plates are well known for use in relief printing on a variety of substrates such as paper, corrugated board, films, foils and laminates. Flexographic printing plates can be prepared from photo-sensitive elements having a photo-polymerizable layer containing an elastomeric binder, a monomer, and a photo-initiator, interposed between a support and a cover sheet or multilayer cover element. One process of making such photo-sensitive elements is described in U.S. Pat. No. 4,460,675 where a previously extruded photo-polymerizable composition is fed into the nip of a calendar and is calendered between a support and a multi-layer cover element to form a photo-polymerizable layer. Upon image-wise exposure of the photo-sensitive element with actinic radiation through a photomask, the exposed areas of the photo-polymerizable layer are insolubilized by photo-polymerization. Treatment with a suitable solvent or solvent mixture removes the unexposed areas of the photo-polymerizable layer leaving a printing relief which can be used for flexographic printing. Such materials and processes are described in U.S. Pat. No. 4,323,637; U.S. Pat. No. 4,427,759; and U.S. Pat. No. 4,894,315.

However, developing the exposed photosensitive element with a solvent or solvent mixture is time consuming since drying for an extended period (0.5 to 24 hours) is necessary to remove entrained developer solution. In addition, these developing systems produce potentially toxic by-product wastes (both the solvent and any material carried off by the solvent) during the development process.

To avoid the problems with solution development, a “dry” thermal development process may be used. In a thermal development process, the photo-sensitive layer, which has been image-wise exposed to actinic radiation, is contacted with an absorbent material at a temperature sufficient to cause the composition in the unexposed portions of the photo-sensitive layer to soften or melt and flow into an absorbent material. See U.S. Pat. No. 3,264,103 (Cohen et al.); U.S. Pat. No. 5,015,556 (Martens); U.S. Pat. No. 5,175,072 (Martens); U.S. Pat. No. 5,215,859 (Martens); and U.S. Pat. No. 5,279,697 (Peterson et al.). In all these cited patents, image-wise exposure is conducted with a silver halide film target in a vacuum frame. The exposed portions of the photosensitive layer remain hard, that is, do not soften or melt, at the softening temperature for the unexposed portions. The absorbent material collects the softened un-irradiated material and then is separated and/or removed from the photosensitive layer. The cycle of heating and contacting the photosensitive layer may need to be repeated several times in order to sufficiently remove the flowable composition from the un-irradiated areas and form a relief structure suitable for printing. Thus remains a raised relief structure of irradiated, hardened composition that represents the desired printing image.

These methods are not able to form flexographic printing plates with feature sizes of less than 20 micrometers.

### BRIEF SUMMARY

In a first embodiment, a method of forming a flexographic printing plate is described and includes disposing a polymeric substrate onto a master tool having a plurality of recesses defining a master tool pattern. A solvent is disposed within the recesses. Then, the solvent is diffused into the polymeric substrate to form a substrate relief pattern that is complementary to the master pattern. and the substrate relief pattern is cured to form a flexographic printing plate.

In another embodiment, a flexographic printing plate includes a polymeric substrate having a major surface and a relief pattern projecting away from the major surface. The relief pattern has a height of at least 20 micrometers and features have a lateral dimension of 15 μm or less.

In a further embodiment, a method of forming a flexographic printing plate includes providing a rigid microstructured master tool having a microstructure, replicating the microstructure onto a polymeric substrate with the rigid microstructured master tool to form a micro-replicated polymeric web master tool, and replicating the microstructure on a second polymeric substrate with the micro-replicated polymeric web master tool to form a micro-replicated flexographic printing plate.

### BRIEF DESCRIPTION OF THE DRAWINGS

The invention may be more completely understood in consideration of the following detailed description of various embodiments of the invention in connection with the accompanying drawings, in which:

FIG. 1 is a schematic diagram of an illustrative flexographic printing apparatus;

FIG. 2 is a block flow diagram of an illustrative method of forming a flexographic printing plate;

FIGS. 3A-3D are schematic cross-sectional diagrams of an illustrative method of forming a flexographic printing plate as described on FIG. 2;

FIG. 4 is a profilometric scan of flexographic printing plates formed in Example 1;

FIG. 5 is a micrographic image of a printed surface of Example 1;

FIG. 6 is a micrographic image of a micro-replicated flexographic printing plate formed in Example 2; and

FIG. 7 is a micrographic image of a printed surface of Example 2.

The figures are not necessarily to scale. Like numbers used in the figures refer to like components, steps and the like. However, it will be understood that the use of a number to refer to a component in a given figure is not intended to limit the component in another figure labeled with the same number.

### DETAILED DESCRIPTION

In the following description, reference is made to the accompanying drawings that form a part hereof, and in which are shown by way of illustration several specific embodiments. It is to be understood that other embodiments are contemplated and may be made without departing from the scope or spirit of the present invention. The following detailed description, therefore, is not to be taken in a limiting sense.

This disclosure relates to flexographic printing plates; and more specifically to solvent-assisted embossing of flexographic printing plates. In particular, this disclosure describes solvent-assisted embossing of a polymeric substrate that may only be partially cured. The solvent diffuses into the polymeric sheet, forming a microstructured polymeric flexographic printing plate following curing of the partially cured microstructured polymeric flexographic printing plate. Unlike conventional methods of forming flexographic printing plates, the methods disclosed herein are capable of forming flexographic printing plates having a feature size lateral dimension of less than 20 micrometers, or less than 15 micrometers, or less than 10 micrometers, and even less than 5 micrometers.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

All scientific and technical terms used herein have meanings commonly used in the art unless otherwise specified. The definitions provided herein are to facilitate understanding of certain terms used frequently herein and are not meant to limit the scope of the present disclosure.

As used herein, “flexographic printing” means a rotary printing process using a flexible printing plate; i.e., a flexographic printing plate. Any material that may be transferred from a flexographic printing plate to a recipient substrate may be “printed”.

As used herein, “flexographic printing plate” refers to a printing plate having features onto which material to be transferred to a recipient substrate may be disposed, wherein the plate or the features are capable of deforming when contacting the recipient substrate (relative to when not contacting the recipient substrate). A flexographic printing plate can be a flat plate that can be attached to a roll or cylinder or the flexographic printing plate can be attached a sleeve attached to a chuck.

As used herein, “feature” means a raised projection of a flexographic printing plate. The raised projection has a distal surface (or land), removed from the bulk of the flexographic printing plate, onto which material may be disposed.

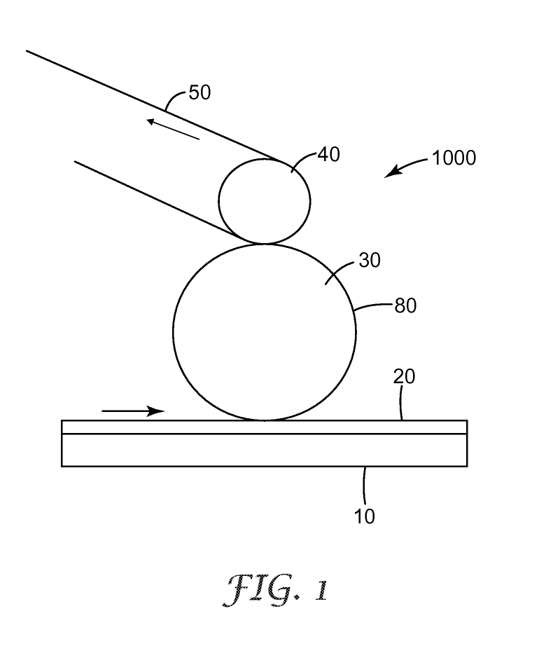

The flexographic printing rolls described herein can be used in any flexographic printing apparatus or system. FIG. 1 is a schematic diagram of an illustrative flexographic printing apparatus 1000. The system 1000 comprises a donor substrate 10 configured to receive material 20 to be printed onto a recipient substrate 50. The system 1000 includes a flexographic roll 30 configured to attachably receive a flexographic printing plate 80 (described below). Flexographic printing plate 80 may be attached to flexographic roll 30 using any suitable technique. One suitable technique includes attaching flexographic plate 80 to flexographic roll 30 using an adhesive.

Flexographic roll 30 is moveable relative to the donor substrate 10 such that material 20 may be transferred from donor substrate 10 to a feature (described below) of a flexographic printing plate 80. The system 1000 depicted in FIG. 1 further includes a substrate roll 40 positioned relative to flexographic roll 30 such that movement of substrate roll 40 relative to flexographic roll 30 is capable of causing recipient substrate 50 to move between flexographic roll 30 and substrate roll 40, allowing material 20 to be transferred from a feature of flexographic printing plate 80.

Flexographic roll 30 and substrate roll 40 depicted in FIG. 1 may be in the form of cylinders and the rolls 30, 40 may rotate about the respective central axes of the cylinders. Such rotation allows printing plate 80 attached to flexographic roll 30 to contact material 20 and then transfer material 20 to recipient substrate 50. Such rotation also allows recipient substrate 50 to move between flexographic roll 30 and substrate roll 40.

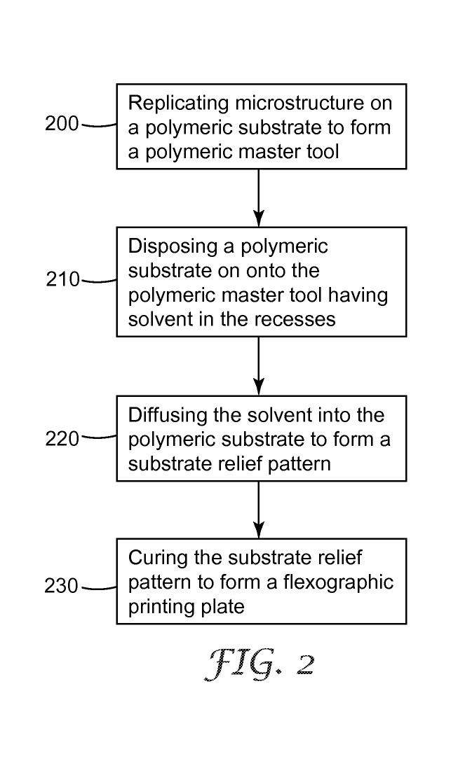

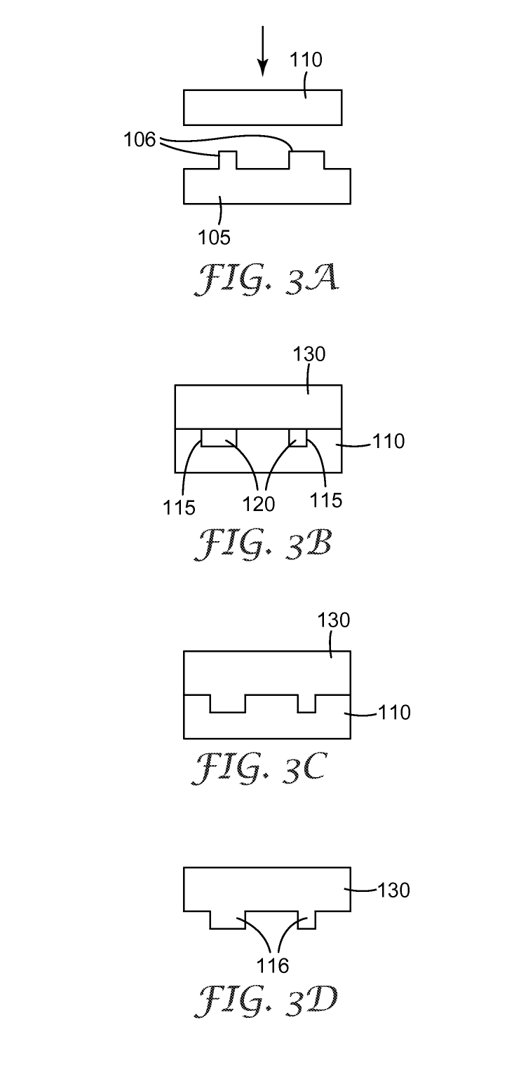

FIG. 2 is a block flow diagram of an illustrative method of forming a flexographic printing plate and FIGS. 3A-3D are schematic cross-sectional diagrams of an illustrative method of forming a flexographic printing plate as described in FIG. 2. In some embodiments, a polymeric master tool 110 is formed (block 200) by replicating microstructure 106 from a rigid master tool 105, such as, a metallic master tool 105. Replication of the microstructure 106 from a rigid master tool 105 to form the polymeric master tool 110 can be performed by any useful method such as, for example, embossing, casting, molding, scribing, and the like. In some embodiments, the master tool is a metallic or rigid substrate that is not polymeric. In other embodiments, the rigid master tool is a rigid polymeric substrate. In some of these embodiments, the rigid master tool has microstructure that is formed by diamond turning techniques (described below) and a flexographic printing plate is replicated by any replication method (e.g., embossing, casting, ect.) with the rigid (metallic or polymeric) master tool.

The rigid master tool 105 having a relief pattern or microstructure 106 described herein can be formed via any useful method. In many embodiments, the rigid master tool features 106 are formed via diamond turning techniques. Diamond turning techniques are described in, for example, U.S. 2006/0234605, which is incorporated by reference herein to the extent it does not conflict with the present disclosure.

The master tool 110, which may be a polymeric master tool, includes a plurality of recesses 115 that correspond and define a master tool recess pattern. A solvent 120 capable of diffusing into a polymeric material is disposed within the pattern of recesses 115 and a polymeric substrate 130 is disposed (block 210) onto the master tool 110 having the solvent 120 in the pattern of recesses 115.

The solvent 120 diffuses (block 220) into the polymeric substrate 130 and swells and/or dissolves a portion of the polymeric substrate 130 adjacent to the solvent 120, causing that portion of the polymeric substrate 130 to conform to the master tool 110 pattern of recesses 115. Once the solvent 120 dissipates, the polymer solidifies to form a relief pattern 116 having a pattern complimentary to the master tool 110 pattern of recesses 115. The relief pattern 116 can be cured (block 230) via radiation (e.g., UV, visible, IR, or e-beam) or heat before and/or after the polymeric substrate 130 is removed from the master tool 110 and utilized as a flexographic printing plate.

The polymeric substrate forming the flexographic printing plate can be formed of any polymeric material that can be swelled and/or dissolved with a solvent and subsequently cured, forming a relief pattern. In many embodiments, the polymeric substrate includes at least one elastomeric binder, at least one curable or photopolymerizable, ethylenically unsaturated monomer, and at least one photoinitiator or initiator system, wherein the photoinitiator is sensitive to actinic radiation. Throughout this specification, actinic radiation (or actinic light) will include ultraviolet radiation and/or visible light.

Examples of elastomeric binders are polyalkadienes, alkadiene/acrylonitrile copolymers; ethylene/propylene/alkadiene copolymers; ethylene/(meth)acrylic acid(meth)acrylate copolymers; and thermoplastic, elastomeric block copolymers of styrene, butadiene, and/or isoprene. In many embodiments, the elastomeric binder includes linear and radial thermoplastic, elastomeric block copolymers of styrene and butadiene and/or isoprene.

For thermally curable polymeric substrates, a thermoplastic binder is used, such as a thermoplastic, elastomeric binder. The thermoplastic binder can be a single polymer or mixture of polymers. Binders include natural or synthetic polymers of conjugated diolefin hydrocarbons, including polyisoprene, 1,2-polybutadiene, 1,4-polybutadiene, and butadiene/acrylonitrile. In many embodiments, the thermoplastic binder is an elastomeric block copolymer of an A-B-A type block copolymer, where A represents a non-elastomeric block, preferably a vinyl polymer and most preferably polystyrene, and B represents an elastomeric block, preferably polybutadiene or polyisoprene. Suitable thermoplastic elastomeric binders of this type include poly(styrene/isoprene/styrene) block copolymers and poly(styrene/butadiene/styrene) block copolymers which are preferred. The non-elastomer to elastomer ratio is preferably in the range of from 10:90 to 35:65. In some embodiments, the thermoplastic elastomeric binder is a mixture of at least two poly(styrene/isoprene/styrene) block copolymers as described in U.S. Pat. No. 5,972,565. The binder can be present in an amount of at least 60% by weight of the photosensitive layer. The term binder, as used herein, encompasses core-shell microgels and blends of microgels and preformed macromolecular polymers, such as those disclosed in U.S. Pat. No. 4,956,252 and U.S. Pat. No. 5,707,773.

Other suitable photosensitive or curable elastomers that may be used include polyurethane elastomers. An example of a suitable polyurethane elastomer is the reaction product of (i) an organic diisocyanate, (ii) at least one chain extending agent having at least two free hydrogen groups capable of polymerizing with isocyanate groups and having at least one ethylenically unsaturated addition polymerizable group per molecule, and (iii) an organic polyol with a minimum molecular weight of 500 and at least two free hydrogen containing groups capable of polymerizing with isocyanate groups. For a more complete description of some of these materials see U.S. Pat. No. 5,015,556.

In many embodiments, the photo-polymerizable material contains at least one ethylenically unsaturated compound photo-polymerizable by actinic radiation. Such compounds are also referred to as monomers or oligomers. Monomers that can be used in the polymeric layer are well known in the art and include, but are not limited to, ethylenically unsaturated, copolymerizable, organic compounds, preferably having at least one terminal ethylenically unsaturated group. Generally the monomers or oligomers have relatively low molecular weights (less than about 30,000). Preferably, the monomers or oligomers have a relatively low molecular weight (less than about 5000), such as, for example, acrylates and methacrylates of monovalent or polyvalent alcohols; (meth)acrylamides; vinyl ethers and vinyl esters; etc., in particular acrylic and/or methacrylic esters of butanediol, hexanediol, diethylene glycol, trimethylol propane, pentaerythritol, etc.; and mixtures of such compounds.

If a polyacrylol oligomer is used, the oligomer should preferably have a molecular weight greater than 1000. A mixture of monofunctional and multifunctional acrylates or methacrylates may be used. Other examples of suitable monomers or oligomers include acrylate and methacrylate derivatives of isocyanates, esters, epoxides and the like. Monomers or oligomers can be appropriately selected by one skilled in the art to provide elastomeric property to the photopolymerizable composition. Examples of elastomeric monomers or oligomers include, but are not limited to, acrylated liquid polyisoprenes, acrylated liquid butadienes, liquid polyisoprenes with high vinyl content, and liquid polybutadienes with high vinyl content, (that is, content of 1-2 vinyl groups is greater than 20% by weight). Further examples of monomers or oligomers can be found in Chen U.S. Pat. No. 4,323,636; Fryd et al., U.S. Pat. No. 4,753,865; Fryd et al., U.S. Pat. No. 4,726,877 and Feinberg et al., U.S. Pat. No. 4,894,315. The monomer and/or oligomer or monomer and/or oligomer mixture can be present in an amount of at least 5%, preferably 10 to 20%, by weight by weight of the photopolymerizable material.

Suitable photoinitiators are individual photoinitiators or photoinitiator systems, such as, for example, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogeno acetophenone, oxysulfonyl ketones, sulfonyl ketones, oxysulfonyl ketones, sulfonyl ketones, benzoyl oxime esters, thioxanthones, camphorquinones, ketocoumarin, Michler's ketone, etc., also mixed with triphenyl phosphine, tertiary amines, etc. In many embodiments, the initiator is sensitive to ultraviolet or visible radiation. Photoinitiators can be generally present in an amount of 0.001-10.0% by weight of the photopolymerizable material.

The thickness of the polymeric substrate can vary over a wide range depending upon the type of flexographic printing plate desired. In many embodiments, the polymeric substrate can be from about 0.05-0.17 cm in thickness, or from 0.25-0.64 cm in thickness or greater, or from 1 to 10 millimeters. Useful flexographic printing plate polymeric substrates are described in U.S. 2005/0196701, and incorporated by reference herein to the extent it does not conflict with the present disclosure. Useful polymeric substrates includes CYREL® brand flexographic printing plate substrates commercially available from DuPont Co. As described above, a flexographic printing plate may be a flat plate that can be attached to a roll; e.g., by mounting tape, or a sleeve attached to a chuck, such as with Dupont™ CYREL® round plates.

Useful solvents include any solvent that can diffuse, swell and/or dissolve the polymeric substrate. The solvent can be organic solvents, aqueous or semi-aqueous solutions, or water. The choice of the solvent will depend primarily on the chemical nature of the polymeric substrate to be swelled and/or dissolved. Suitable organic solvents include aromatic or aliphatic hydrocarbon, and aliphatic or aromatic halohydrocarbon solvents, for example, n-hexane, petrol ether, hydrated petrol oils, limonene or other terpenes or toluene, isopropyl benzene, etc., ketones such as methyl ethyl ketone, halogenated hydrocarbons such as chloroform, trichloroethane, or tetrachloroethylene, esters such as acetic acid or acetoacetic acid esters, or mixtures of such solvents with suitable alcohols. Suitable semi-aqueous solvents usually contain water and a water-miscible organic solvent and an alkaline material.

The methods described herein allow for flexographic printing plates having feature sizes that are smaller than previously known. In particular, these flexographic printing plates have a relief pattern of features that project away from the plate surface a distance (i.e., a height) of at least 20 micrometers, or at least 25 micrometers, or at least 50 micrometers, or at least 100 micrometers, have a lateral dimension of 15 micrometers or less, or 10 micrometers or less, or 5 micrometers or less, and can be spaced apart in a lateral dimension of at least 100 micrometers, or at least 150 micrometers, or at least 250 micrometers, or at least 500 micrometers, without the sagging problems associated with prior forming methods and flexographic printing plates.

### EXAMPLES

### Example 1

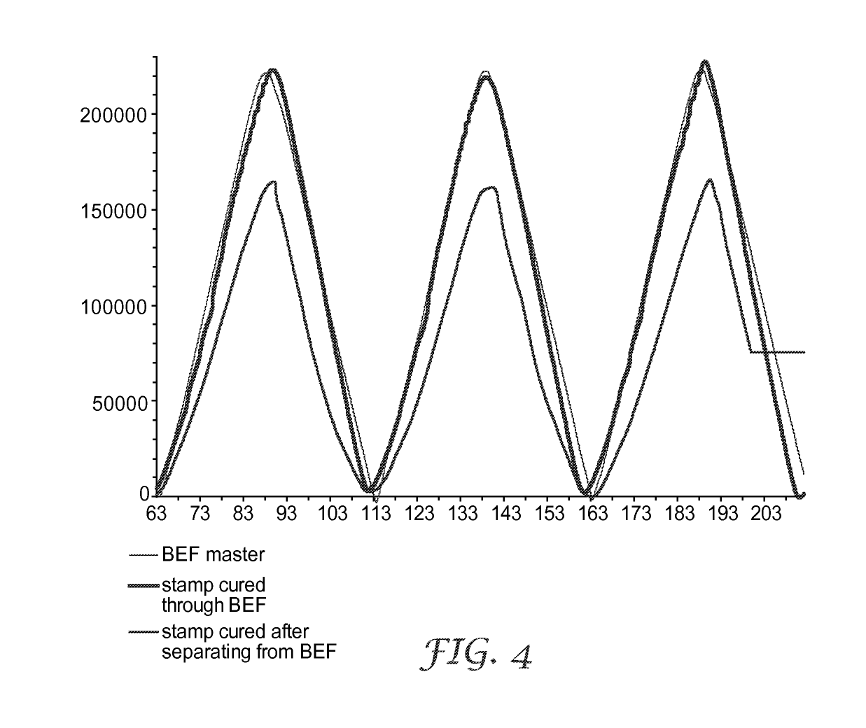

A micro-flexographic printing plate was prepared by taking a polymeric film with a micro-replicated linear prismatic structure (BEF 90/50, commercially available from 3M Co.) a profilometric scan of this master structure is illustrated in FIG. 4 and referred to as BEF MASTER, depositing a thin layer of methyl ethyl ketone on its structured surface, and then positioning CYREL® flexographic plate (type TDR B 6.35 mm thick, with removed cover sheet, commercially available from DuPont Co.) on the top of the micro-replicated surface. After 15 hours, the CYREL® plate was exposed to UV radiation through the attached micro-replicated film in a UV processor (Fusion UV Curing lamp, model MC-6RQN, Rockville, Md., 200 watt/in, mercury lamp, run at approximately 5 fpm) and then the micro-replicated flexographic printing plate was detached from the BEF master. A profilometric scan of this micro-replicated flexographic printing plate illustrating the features is shown in FIG. 4 and referred to as STAMP CURED THROUGH BEF. The x-axis scale is in micrometers and the y-axis scale is in angstroms.

FIG. 4 also illustrates a profilometric scan of another micro-replicated flexographic printing plate formed according to the above method except that the micro-replicated flexographic printing plate was cured after it was detached from the BEF master. A profilometric scan of this micro-replicated flexographic printing plate is shown in FIG. 4 and referred to as STAMP CURED AFTER SEPARATING FROM BEF.

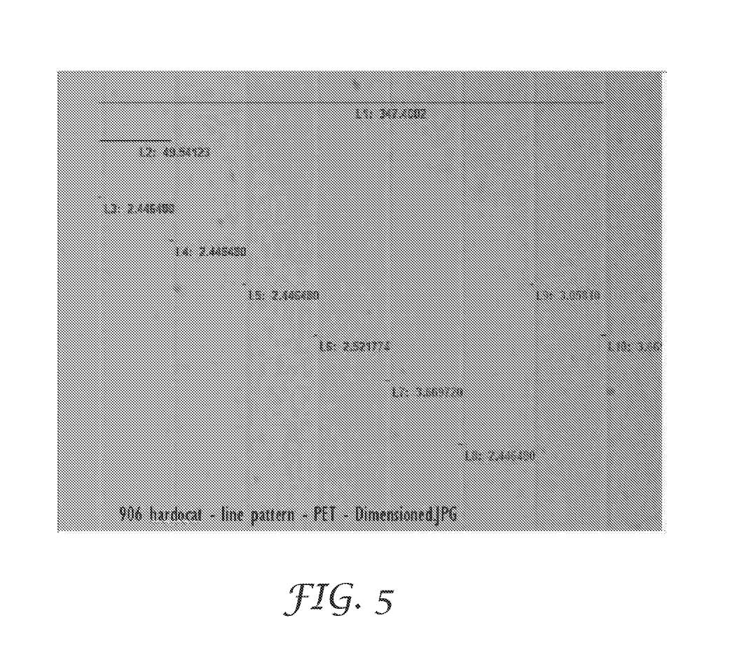

The micro-replicated flexographic printing plate of STAMP CURED THROUGH BEF was attached to a 12.7 cm-diameter glass cylinder by flexographic mounting tape (type 1120, commercially available from 3M Co.). A thin layer of 906 hardcoat (3M's 906 hardcoat is a 33 wt % solids ceramer hardcoat dispersion containing 32 wt % 20 nm SiO₂ nano-particles, 8 wt % N,N-dimethyl acrylamid, 8 wt % methacryloxypropyl trimethoxysilane and 52 wt % pentaerythritol tri/tetra acrylate (PETA) in IPA) was deposited onto a clean in glass slide (available from Erie Scientific Company, Portsmouth, N.H.) by dip coating at 0.03 meters per minute from the 906 hardcoat solution in IPA (25 wt % solids), and drying that glass slide in open air. The flexographic printing plate was then rolled by hand in that layer of hardocat and then rolled onto a clean 125 micrometer PET i.e., poly(ethylene terephtalate) film (available from DuPont Co). This PET film with printed lines was sent through a UV processor (Fusion UV Curing lamp, model MC-6RQN, Rockville, Md., 200 watt/inch, mercury lamp, purged by nitrogen to approximately 50 ppm of oxygen, run at approximately 1.5 meters per minute). The resulting printed 906 hardcoat lines were approximately 2.5 micrometers wide and spaced apart by approximately 50 micrometers forming a parallel line pattern illustrated with the micrographic image of FIG. 5.

### Example 2

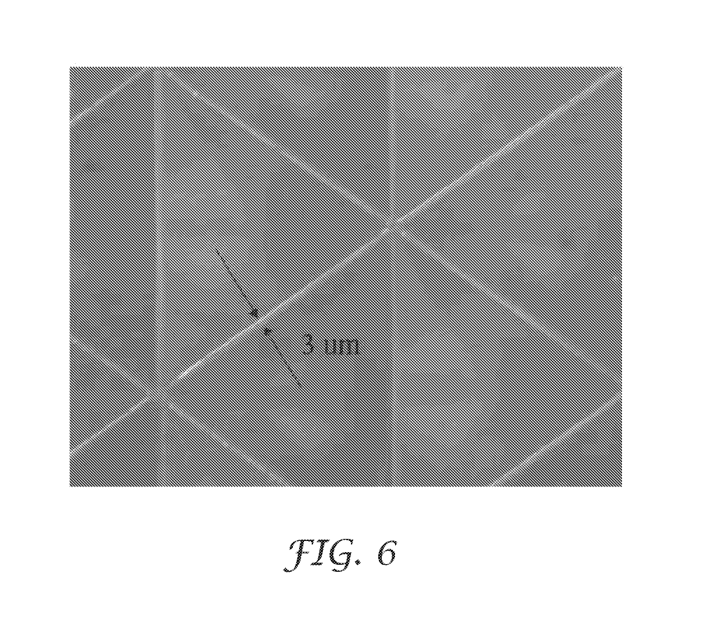

A micro-flexographic printing plate was prepared by taking a polymeric film with a microrepliciated corner-cube structure, depositing a small amount of methyl ethyl ketone on the master tool structured surface, and then positioning a CYREL® flexographic plate (type TDR B 6.35 mm thick, with removed cover sheet, available from DuPont Co.) on the top of the master tool micro-replicated surface. After 15 hours, the CYREL® plate was exposed to UV radiation through attached micro-replicated film in a UV processor (Fusion UV Curing lamp, model MC-6RQN, Rockville, Md., 200 watt/in, mercury lamp, run at approximately 1.5 meters per second) and then the micro-replicated flexographic printing plate was detached from the master tool. This micro-replicated flexographic printing plate was then attached to a 12.7 cm-diameter glass cylinder by flexographic mounting tape (type 1120, commercially available from 3M Co.). A micrographic image of this micro-replicated flexographic printing plate illustrating the features is shown in FIG. 6.

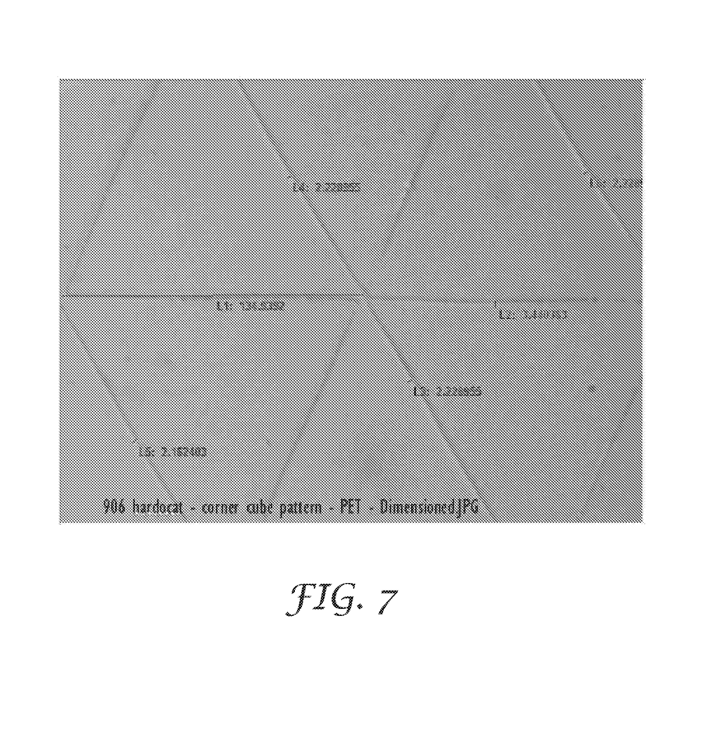

A thin layer of 906 hardcoat (described in Example 1) was deposited onto a clean glass slide by dip coating at 0.03 meters per minute from a 906 hardcoat solution in IPA (25 wt % solids), and drying that glass slide in open air. The flexographic printing plate was then rolled by hand in that layer of hardocat and then rolled onto a clean 125 micrometer PET i.e., poly(ethylene terephtalate) film (available from DuPont Co). This PET film with printed lines was sent through a UV processor (Fusion UV Curing lamp, model MC-6RQN, Rockville, Md., 200 watt/inch, mercury lamp, purged by nitrogen to approximately 50 ppm of oxygen, run at approximately 1.5 meters per minute). The resulting printed lines were approximately 3 micrometers wide and 135 micrometers long forming a triangular pattern as illustrated in the micrographic image shown in FIG. 7.

Thus, embodiments of the SOLVENT-ASSISTED EMBOSSING OF FLEXOGRAPHIC PRINTING PLATES are disclosed. One skilled in the art will appreciate that embodiments other than those disclosed are envisioned. The disclosed embodiments are presented for purposes of illustration and not limitation, and the present invention is limited only by the claims that follow.

What is claimed is:

1. A method of forming a flexographic printing plate, comprising:
disposing a polymeric substrate onto a master tool having a plurality of recesses defining a master tool pattern, with a solvent disposed within the recesses;
diffusing the solvent into the polymeric substrate to form a substrate relief pattern that is complementary to the master pattern; and
curing the substrate relief pattern to form a flexographic printing plate.

2. A method according to claim 1, wherein the substrate relief pattern comprises features having a lateral dimension of 15 μm or less.

3. A method according to claim 1, wherein the substrate relief pattern comprises features having a lateral dimension of 5 μm or less.

4. A method according to claim 1, wherein curing the substrate relief pattern comprises exposing the substrate relief pattern to radiation.

5. A method according to claim 1, wherein curing the substrate relief pattern comprises exposing the substrate relief pattern to heat.

6. A method according to claim 1, further comprising removing the polymeric substrate from the master tool after the diffusing step.

7. A method according to claim 1, further comprising flexographic printing a substrate with the flexographic printing plate.

8. A method according to claim 1, wherein the polymeric substrate is partially cured before the disposing step.

9. A method according to claim 1, wherein the curing step occurs while the substrate relief pattern is disposed within the master pattern.

10. A method according to claim 1, further comprising removing the polymeric substrate from the master tool after the curing step.

11. A method according to claim 1, wherein the master tool is a polymeric master tool.

12. A flexographic printing plate comprising;
a polymeric substrate having a major surface and a relief pattern projecting away from the major surface, the relief pattern having a height of at least 20 micrometers and the relief pattern comprises features having a lateral dimension of 15 μm or less.

13. A flexographic printing plate according to claim 13, wherein the relief pattern comprises features having a lateral dimension of 5 μm or less.

14. A flexographic printing plate according to claim 13, wherein the relief pattern has a height of at least 25 micrometers.

15. A flexographic printing plate according to claim 13, wherein relief pattern comprises features spaced apart in a lateral dimension of at least 100 μm.

16. A flexographic printing plate according to claim 13, wherein relief pattern comprises features spaced apart in a lateral dimension of at least 500 μm.

17. A flexographic printing plate according to claim 13, wherein the polymeric substrate is partially cured.

18. A method of forming a flexographic printing plate, comprising:
providing a rigid master tool having a microstructure;
replicating the microstructure on a polymeric substrate with the rigid master tool to form a micro-replicated polymeric web master tool; and
replicating the microstructure on a second polymeric substrate with the micro-replicated polymeric web master tool to form a micro-replicated flexographic printing plate.

19. A method according to claim 18 wherein the microstructure comprises features having a lateral dimension of 10 μm or less.

20. A method according to claim 19 further comprising forming the rigid master tool microstructure by diamond turning.

21. A method of forming a flexographic printing plate, comprising:
providing a rigid master tool having a microstructure wherein the microstructure is formed by diamond turning; and
replicating the microstructure on a polymeric substrate with the rigid master tool to form a micro-replicated flexographic printing plate.
